(19) United States
(12) Patent Application Publication
(10) Pub. No.: US 2019/0313532 A1
(43) Pub. Date: Oct. 10, 2019

(54) Sensor Device for a Vehicle, Motor Vehicle

(71) Applicant: Robert Bosch GmbH, Stuttgart (DE)

(72) Inventors: Bernd Tepass, Beilstein (DE); Marlon Ramon Ewert, Untergruppenbach (DE); An Leurs, Schwieberdingen (DE); Daniel Schoenfeld, Abstatt (DE)

(21) Appl. No.: 16/340,927

(22) PCT Filed: Aug. 8, 2017
(86) PCT No.: PCT/EP2017/070062

§ 371 Date: Apr. 10, 2019

(30) Foreign Application Priority Data
Oct. 14, 2016 (DE) 10 2016 220 031.3

(51) Int. Cl. H05K 1/18; H05K 3/28; H05K 1/14; G01D 11/24; B60R 19/48

(52) U.S. Cl. CPC H05K 1/189; H05K 3/284; H05K 1/141; H05K 1/147; H05K 2203/1327; B60R 19/483; H05K 2201/10151; H05K 2203/1316; G01D 11/245

(57) ABSTRACT

A sensor device for a vehicle, in particular a motor vehicle, includes at least one sensor module and at least one connecting line connected to the sensor module for making electrical contact with the sensor module. The sensor module has at least one sensor. The sensor module is positioned on the connecting line, which is in the form of a conductor foil, and is encased by an overmolding which at least partially encloses the conductor foil.

The invention relates to a sensor device for a vehicle, in particular a motor vehicle, having at least one sensor module and having at least one connecting line that is connected to the sensor module so as to make electrical contact with the sensor module, wherein the sensor module comprises a sensor.

Moreover, the invention relates to a car body part for a vehicle having a sensor device of this type.

Furthermore, the invention relates to a method for producing a corresponding sensor device or for producing a corresponding car body part.

### PRIOR ART

Sensor devices of the type mentioned in the introduction are known from the prior art. In order to increase the safety of occupants and other traffic participants, it is known to provide safety devices on the vehicle that particularly in the event of an accident protect the occupants and/or other traffic participants such as for example pedestrians from becoming injured. In particular, airbag devices, belt-tensioners and the like are known as safety devices. The safety devices are controlled in this case in dependence upon sensor data from sensor devices that detect a collision by way of example with the other traffic participant, in particular pedestrians. Systems are known for detecting accidents involving pedestrians, said systems comprising two or more acceleration sensors and/or a pressure hose-based system. These systems are then arranged by way of example in a bumper of the vehicle in order to detect the vehicle colliding with an object in the environment. Nowadays, in order to detect collisions on a vehicle longitudinal side sensor devices are used that are arranged on the B-, C- or D-columns of the vehicle in particular with at least one acceleration sensor or in the vehicle door in particular with at least one pressure sensor. Nowadays, in order to detect collisions with objects in front of the vehicle, acceleration sensors are used that are located by way of example in the central control device and/or along a flexible cross member of the vehicle. The signals output by the sensors are further processed on the basis of algorithms of a control device, in particular an airbag control device, in order to decide whether to trigger the respective safety device of the vehicle.

Sensor devices having rotational speed detectors are also known as sensors that are also frequently used in the motor vehicle. Rotational speed detectors for evaluating magnetized rotational speed sensors usually comprise at least one measuring element or rather sensing element that is configured as a half-bridge or full bridge and is generally installed in an ASIC. The term ‘a sensor’ is understood below to be the entirety of a measuring element and ASIC, in other words the circuit that initially receives the measurement signal. This sensor is usually connected by means of two current rails to two connector pins.

Usually, the sensors are attached as a sensor module to a dedicated housing and a connecting line so as to make electrical contact with a car body part of the vehicle, such as by way of example with the bumper or with a door cladding. A screw or clip connection is frequently provided so as to make the attachment. The electrical contact is often made by way of a connector that is mounted on a cable harness. Fundamentally, it is also known to use a conductor foil so as to electrically contact electronic components, said conductor foil being configured in a flexible manner and carrying on at least one or between at least two carrier foils one or more electrical conductor tracks. By virtue of the in particular flat structure of the conductor foil, it is possible to integrate said conductor foil in existing structures in a manner which saves installation space.

### DISCLOSURE OF THE INVENTION

The sensor device in accordance with the invention and having the features of claim 1 has the advantage that it provides a compact sensor device that is easy to handle and may be advantageously integrated into the vehicle and facilitates the positioning of the sensor module or sensor modules. In addition, it is provided in accordance with the invention that the sensor module that is arranged on the connecting line that is configured as a conductor foil is encased by an overmolding that at least in part encloses the conductor foil. Consequently, the sensor module is held against the conductor foil in a simple manner by means of the overmolding. As a consequence, the position of the sensor module on the conductor foil is predetermined and this facilitates the procedure of mounting the sensor device in the vehicle. It is preferred that sensor devices of this type may be arranged in the vehicle door, however they may also be arranged by way of example in a bumper or in one of the vertical columns of the vehicle. The conductor foil preferably comprises on one face an adhesive means by means of which the conductor foil may be attached or at least pre-mounted in a simple manner to a car body element, by way of example to a cladding element. Thus, the conductor foil is preferably configured from multiple layers and comprises in particular an adhesive layer that is preferably covered by a removable protective layer prior to the mounting procedure.

In accordance with a preferred embodiment of the invention, it is provided that the sensor is configured as a pressure sensor. It is possible in this respect using the sensor device to detect a hydraulic, pneumatic or mechanical pressure. Alternatively, the sensor is preferably configured as a rotational speed detector in order to detect by way of example the rotational speed of a drive wheel or of a crank shaft of the motor vehicle.

In accordance with a preferred embodiment of the invention, it is provided that multiple sensor modules are arranged on the conductor foil and in each case said sensor modules are encased by an overmolding that at least in part encloses the conductor foil. As previously described, this consequently determines the arrangement of the sensor modules on the conductor foil. As a consequence, the distances between the adjacent sensor modules are determined in particular prior to the mounting procedure, as a consequence of which the actual mounting procedure may be performed rapidly yet still accurately. Each sensor module is electrically connected to at least one electrical conductor track of the conductor foil. Said connection may be produced by way of example during the production procedure by means of soldering procedure or by means of a procedure where physical contact is made. In particular, the conductor foil comprises by virtue of the conductor foil contact sections in which the one or the multiple conductor tracks comprises/comprise a widened or enlarged contact area in comparison to the remaining course of the conductor tracks, with the result that a simple electrical contact of the sensor module is ensured at this site. If multiple sensor modules are provided, it is possible to configure said sensor modules in an identical manner, in other words by way of example they may all comprise a pressure sensor or a rotational speed detector or the sensor modules are configured differently with the result that by way of example a sensor module comprises a pressure sensor and a different rotational speed detector.

It is furthermore provided that the overmolding comprises at least one attachment means for attaching the sensor module to a car body part of the vehicle. The attachment means may be by way of example a latching means or a clamping means that cooperates with a corresponding mating means of the car body part of the vehicle in order to be able to attach the sensor module to the car body part in particular in a releasable manner. The overmolding is configured by way of example in such a manner that the housing that is formed by means of the overmolding comprises connecting receptacles and/or connecting protrusions that cooperate with corresponding connecting protrusions or rather connecting receptacles of the car body part so as to attach the sensor module. In particular, the attachment means are configured at least in part in an elastically deformable manner in order to render it possible to latch or rather clip in the sensor module to or in the car body part.

Furthermore, it is preferably provided that the overmolding at least in part simultaneously forms the car body part. Consequently, the sensor device is an integral component of the car body part and is already taken into consideration during the production of the car body part. As a consequence, although this renders it more difficult to replace the sensor device itself, the production of the car body part with the sensor function is made easier.

It is preferred that the overmolding is configured in an elastically deformable manner. As a consequence, it is ensured that the sensor module is overall elastically deformable in order to render it possible to subsequently form the sensor module on a car body part. As a consequence, the sensor module and accordingly the sensor device are mounted in a simple and precisely-fitting manner.

In an expedient manner, the respective sensor module comprises a carrier on which the sensor is arranged. This carrier is in particular configured as a so-called interposer that comprises electrical conductor tracks that render it possible to allocate the electrical contacts individually. Thus, the first ends of those conductor tracks that are allocated to the sensor are arranged closer to one another than the other ends of the conductor tracks that make contact with the conductor tracks of the conductor foil. As a consequence, a reliable contact with the sensor is ensured and simultaneously an undesired short circuit in particular in the region where contact is made with conductor foil is prevented in a simple manner. It is preferred that the sensor is already mounted on the carrier prior to the mounting procedure. In so doing, the procedure of mounting the respective sensor on the carrier may be performed in a conventional manner.

Furthermore, it is preferably provided that the carrier is configured in a flexible manner. In particular, it is ensured as a consequence that the shape of the sensor module itself matches a car body part that comprises by way of example a curvature, as is usual by way of example in the case of bumpers. In particular, the electronic/electrical components of the sensors are preferably likewise configured so as to deform without becoming damaged. In particular, by way of example integrated circuits are configured for this purpose as thin in such a manner that they are elastically deformable.

In accordance with a preferred further development of the invention it is provided that the conductor foil is configured in strips and comprises at least one carrier foil that is able to deform in an elastic and/or plastic manner and at least one conductor track that is able to deform with the carrier foil in an elastic and/or plastic manner. The conductor foil consequently extends in a strip-shaped manner or rather in a ribbon-shaped manner and is provided along its course with one or multiple sensor modules, as previously described. By virtue of the fact that the carrier foil(s) and conductor track(s) is able to deform in an elastic and/or plastic manner, it is rendered possible to insert and configure the conductor foil in a simple manner to suit the respective car body part.

The car body part in accordance with the invention and having the features of claim 10 is characterized by a car body part and at least one sensor device that is configured in accordance with the invention and is attached to the car body part. In so doing, this achieves the already mentioned advantages.

In particular it is provided that the sensor device is configured integrated into the car body part. It is preferred that the car body part is configured for this purpose at least in parts as an overmolding of the sensor device. In particular, the car body part forms an additional casing or the previously mentioned casing for the respective sensor module of the sensor device.

The method in accordance with the invention for producing a sensor device, in particular for producing the sensor device in accordance with the invention, as has already been described above, or for producing the above described car body part is characterized by the features of claim 12. In so doing, it is provided that initially the sensor module is arranged on the connecting line that is formed as a conductor foil and that subsequently the conductor foil and the sensor module are overmolded in such a manner that the sensor module is encased by an overmolding that also at least in part encloses the conductor foil. As a consequence, this achieves the already mentioned advantages.

Further advantages and preferred features and feature combinations arise in particular from the description above and also from the claims.

The invention is to be explained in detail below with reference to the drawing. In the drawing:

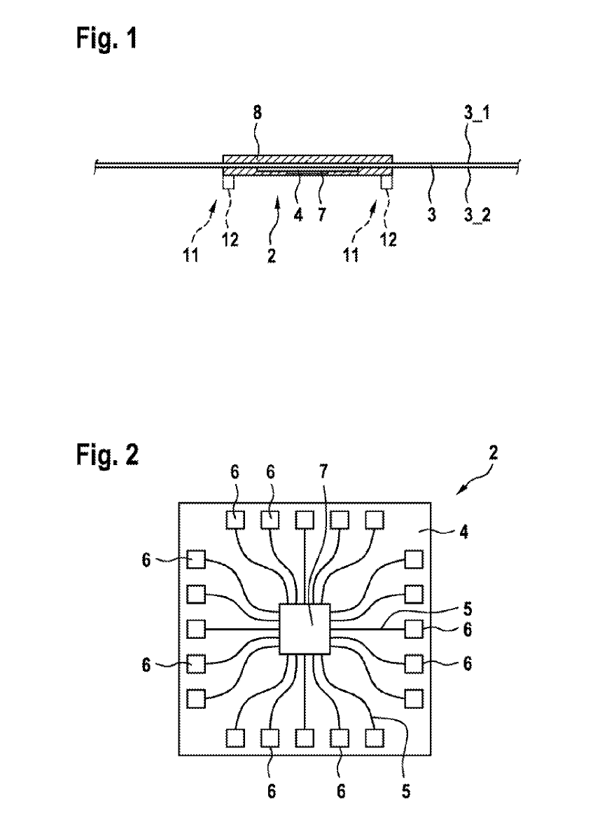

FIG. 1 illustrates a sensor device in a simplified sectional view,

FIG. 2 illustrates a sensor module of the sensor device in a simplified plan view,

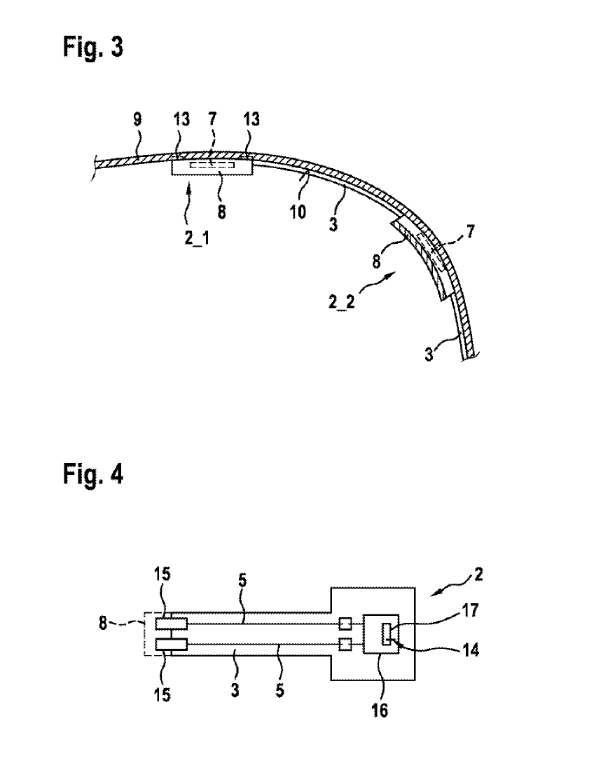

FIG. 3 illustrates a car body part of a motor vehicle in a simplified view and

FIG. 4 illustrates the sensor device in accordance with a further exemplary embodiment.

FIG. 1 illustrates in a simplified longitudinal sectional view a sensor device 1 that comprises a sensor module 2 and a conductor foil 3. The conductor foil 3 is configured in a strip-shaped or rather ribbon-shaped manner and is formed in particular from at least one carrier foil 3_1 on which multiple electrically conductive conductor tracks 3_2 are arranged. The conductor foil 3 is manufactured in particular in a known manner.

FIG. 2 illustrates the sensor module 2 in a simplified plan view. The sensor module 2 comprises a carrier 4 that is manufactured from an electrically non-conductive and elastically deformable material. Multiple conductor tracks 5 are arranged on the carrier 4 and said conductor tracks extend in a star-shaped manner from the outside inward or in the opposite direction. Multiple electrically conductive contact sites 6 are arranged respectively on the outer edges of the carrier 4, wherein for reasons of clarity of the overview in this case only some conductor tracks 5 and contact sites 6 are provided with reference numerals. The contact sites 6 are connected to respectively one end of one of the conductor tracks 5, by way of example are configured in one piece therewith. The conductor tracks 5 lead away from the contact sites 6 into the middle of the carrier 4 where a pressure sensor 7 is arranged and are electrically contacted by means of the free ends of the conductor tracks 5. Corresponding contact sites are provided on the other ends of the conductor tracks 5, not visible in FIG. 2, so as to contact the pressure sensors 7. Consequently, the carrier 4 forms together with the conductor tracks 5 and the respective contact sites 6 a so-called interposer that renders it possible to allocate the electrical contacts of the pressure sensor 7 individually to the contact sites 6 that in comparison to the contact sites of the pressure sensor 7 are arranged further apart from one another and thus may be contacted in a simpler manner. In this case, the contact sites 6 are electrically connected to the conductor tracks 3_2 of the conductor foil 3.

The carrier 4 is attached to the conductor foil 3 in such a manner that the contact sites 6 are in physical contact with the corresponding conductor tracks 3_2 of the conductor foil 3 in order to produce an electrical connection. Optionally, the contact sites 6 are welded or soldered to the respective conductor tracks 3_2 in order to permanently ensure the electrical contact.

The sensor module 2 that is lying against the conductor foil 3 is encased by an overmolding 8 that also encloses in part the conductor foil 3. Consequently, by virtue of the overmolding 8 on the one hand the sensor module 2 itself is encased and protected against external influences and on the other hand as a result the sensor module 2 is attached to the conductor foil 3 in a simple manner. The sensor module 2 and the conductor foil 3 in this respect form an advantageous unit that renders it possible in a simple manner to arrange and attach the sensor device 1 to a car body part. The sensor device 1 is in particular connected by means of the conductor foil 3 to a control device (not illustrated in the figure) that on the basis of sensor data ascertained and accordingly provided by the pressure sensor 7 controls a safety device of a vehicle, such as by way of example an airbag device or a belt tensioner.

The sensor device 1 may be attached in a simple manner to a car body part so as to arrange said sensor device in the vehicle. FIG. 3 illustrates for this purpose in an exemplary embodiment a car body part 9 of a motor vehicle in a cross sectional view, wherein the car body part 9 represents a vehicle door structure, by way of example door cladding, of the motor vehicle. The car body part 9 is at least in part configured with a curvature, wherein the sensor device 1 that is arranged on the inner face of said car body part in the current exemplary embodiment comprises two sensor modules 2_1, 2_2, which are arranged on the conductor foil 3 as previously described. By virtue of the fact that the sensor modules 2_1, 2_2 are encased in each case together with the conductor foil 3 by the overmolding 8, their spacing with respect to one another on the conductor foil 3 is predetermined, as a result of which the procedure of mounting the sensor device 1 with multiple sensor modules 2 on the car body part 9 is simplified. By virtue of the flexible configuration of the conductor foil 3 it is possible to guide said conductor foil in a simple manner along the inner face 10 of the curved car body part 9 with the result that said conductor foil is arranged/may be arranged on the car body part 9 in an installation space-saving and optimal manner.

In accordance with a further exemplary embodiment that is likewise illustrated in FIG. 3, the sensor device 1 is configured integrated in the car body part 9. For this purpose, the car body part 9 itself forms a part of the overmolding 8 of the sensor module 2_2, that is illustrated on the right-hand side of FIG. 3. Consequently, it is possible for the car body part 9 to be simultaneously formed with the overmolding 8, which results in a particularly compact and easy-to-handle unit. It is also conceivable that the respective sensor module 2_2 is subsequently enclosed by an additional overmolding 8 of the car body part 9 and as a result said sensor module is held against said car body part. It is preferred that both sensor modules 2_1, 2_2 are attached to the car body part 9 in accordance with the further exemplary embodiment. It goes without saying that it is also possible to arrange more than two sensor modules 2 on the conductor foil 3. Consequently, the car body part 9 together with the sensor device 1 forms an advantageous car body part that is already provided with a pressure sensor for controlling safety devices of the motor vehicle.

The integration of the sensor device 1 in the car body part 9 provides the advantage of a covered installation that prevents the end user interfering with the electronic system. As a consequence, the system safety is increased. On account of the minimal thickness of the sensor device 1, the mechanical structural strength of the car body part 9 is not influenced or is hardly influenced by the integration of the sensor device 1 in the car body part 9. The sensor function of the sensor device 1 may be combined as an integral component of the car body 9 with other functions that are integrated directly in the final component, such as by way of example an integrated electrical energy storage device, heating wires or induction coils, as a result of which the multi-functionality of the car body part is implemented in a conductive structural manner.

In particular by virtue of the integrated design of the sensor device 1, the sensor is positioned and arranged on the conductor foil and accordingly on the car body part 9 in a highly precise manner, as a result of which it is possible to reduce the number of steps during the production procedure and during a subsequent testing of the functionality.

It is cost-effective and less time-consuming to produce the sensor device 1 using the foil-based back-molding technology or rather overmolding technology or alternatively by means of a foil-based integration in the car body part 9. In order to mount the sensor device 1 it is also possible to provide that the overmolding 8 comprises in each case one or multiple attachment means that so as to attach the respective sensor module 2 lie against the car body part 9. Thus, it is provided in accordance with the exemplary embodiment illustrated by the broken line in FIG. 1 that the attachment means 11 are configured as connecting protrusions 12 that may be plugged into corresponding connecting receptacles 13 of the car body part 9. In an expedient manner, the connecting protrusions 12 and connecting receptacles 13 are configured so as in each case to form a press-fit arrangement with the result that the respective sensor module 2 may be mounted or at least may be pre-mounted in a simple manner on the car body part 9. It is also conceivable to configure the attachment means as a latching means in order to render it possible to latch the respective sensor module 2 in a positive-locking manner to the car body part 9.

In so doing, the production costs may in addition be further reduced by virtue of the fact that a 2R2-production line is used or that open semi-conductors are mounted directly with the target of reducing the surface area of the foil. The production costs are also reduced by virtue of the fact that it is simple to mount the sensor device 1 on the vehicle and accordingly on the car body part 9, by way of example by means of directly integrating the sensor device 1 into the car body part 9 as a FRP (fiber-reinforced plastic) structure in the case of a molding procedure, in particular in the case of a LCM (liquid composite molding) procedure.

By virtue of the technique used, the pressure sensors 7 of the sensor modules 2 are directly integrated in a simple manner into the car body part 9, in particular into the bumper. It goes without saying that the car body part 9 may also be a door cladding. It is also conceivable to arrange the sensor device 1 in a vehicle seat. It is possible by using direct connecting techniques to achieve simple electrical connections of the components of the sensor device 1. Furthermore, it is possible by virtue of the advantageous encasing of the sensor modules 2 to attach a customer-specific plug connector directly to the conductor foil 3. By virtue of the flexible design of the sensor device 1, it is also possible to subsequently deform the sensor device 1, as is already illustrated using the example in FIG. 3. By virtue of using a suitable folding technique, it is possible to produce complex structures and geometries up to and including stacking multiple sensor modules one above the other. If the conductor foil 3 comprises more than 2 layers of carrier foil and conductor tracks, it is thus possible to also achieve complex electrical circuits by virtue of a multiple layer structure. It is preferred that the carrier material of the conductor foil 3 and optionally also the carrier 4 of the respective sensor module 2 are produced from a material that is able to deform in an elastic and plastic manner with the result that the carrier foil 3 and where appropriate the carrier 4 may be stretched or rather extended and may be deformed in all directions. In particular, it is possible as a result of the carrier 4 being able to deform to configure the sensor module 2 itself in an appropriate manner to suit as an insertion part with the result that said sensor module fits in a dimensionally accurate manner into a three dimensional car body part or rather said sensor module may be attached to said car body part.

Whereas in accordance with the preceding exemplary embodiments it is provided that the sensor module 2 comprises in each case a pressure sensor 7 as a sensor, in accordance with a further exemplary embodiment that is illustrated in FIG. 4 it is provided that the sensor module 2 comprises a rotational speed detector 14 in lieu of the pressure sensor or in addition to the pressure sensor, said rotational speed detector being arranged on the conductor foil 3 and being connected by means of conductor tracks 5 to the connector pins 15. In a similar manner to the sensor 14, the connector pins 15 are preferably also overmolded with a synthetic material, wherein the overmolding 8 in this case lies in part at a distance from the connector pins 15 with the result that it is possible to electrically contact said connector pins from the outside by means of a corresponding contact connector. The sensor 14 comprises an application specific integrated circuit (ASIC) 16 that is formed on a flexible carrier, as previously described, and is arranged on the conductor foil 3. The circuit 16 comprises preferably integrated the measuring element 17 of the rotational speed detector 14 that is preferably configured as a half-bridge or full bridge.

It is possible by virtue of the advantageous design to realize the sensor device 2 having the rotational speed detector smaller than previously, wherein the production costs are reduced by virtue of directly over-spraying or rather overmolding the conductor foils 3 that support the circuit 16 and the sensing element and accordingly the measuring element 17. Furthermore, the number of vulnerable connection sites is reduced. The sensor 14 is positioned precisely on the carrier foil 3 during the mounting procedure and is delivered as a supplier part on or rather in a/the carrier. It is preferred that the framework conditions with regard to the tolerance position are structured in such a manner that it is not necessary for the position to be adjusted once the conductor foil 3 has been integrated in the carrier component and further mounting steps with the requirements for the position of the sensor module 2 to be adjusted are not necessary. As previously already described, it is also possible here to use planar mounting technology for fitting in particular the integrated components, as a result of which further cost advantages are achieved.

1. A sensor device for a vehicle, comprising:
at least one sensor module including at least one sensor;
a conductor foil connected to the at least one sensor module so as to make electrical contact with the at least one sensor module, the at least one sensor module arranged on the conductor foil; and
at least one overmolding configured to encase the at least one sensor module and to at least in part enclose the conductor foil.

2. The sensor device according to claim 1, wherein the at least one sensor is configured as a pressure sensor or as a rotational speed detector.

3. The sensor device according to claim 1, wherein the at least one sensor module includes multiple sensor modules arranged on the conductor foil and in each case said sensor modules are encased by a respective overmolding of the at least one overmolding that at least in part encloses the conductor foil.

4. The sensor device according to claim 3, wherein the respective overmolding comprises at least one attachment structure configured to attach a respective sensor module of the at least one sensor module to a body part of the vehicle.

5. The sensor device according to claim 1, wherein the at least one overmolding at least in part simultaneously forms a car body part of the vehicle.

6. The sensor device according to claim 1, wherein the at least one overmolding is configured in an elastically deformable manner.

7. The sensor device according to claim 1, wherein the at least one sensor module comprises a carrier on which the at least one sensor is arranged.

8. The sensor device according to claim 7, wherein the carrier is configured in a flexible manner.

9. The sensor device according to claim 1, wherein the conductor foil is configured in a strip-shaped manner and comprises at least one carrier foil that is deformable in an elastic and/or plastic manner and at least one conductor track that is deformable with the at least one carrier foil in the elastic and/or plastic manner.

10. The sensor device according to claim 1, wherein the sensor device is attached to a body part for the vehicle.

11. The sensor device according to claim 10, wherein the sensor device is integrated in the body part.

12. A method for producing a sensor device including at least one sensor module, comprising:
connecting at least one conductor foil to the at least one sensor module so as to make electrical contact with the at least one sensor module, the at least one sensor module including at least one sensor;
encasing the at least one sensor module with an overmolding; and
enclosing, at least in part, the at least one conductor foil with the overmolding.
